(19) United States
(12) Patent Application Publication
(10) Pub. No.: US 2026/0293399 A1
(43) Pub. Date: Sep. 24, 2026

(54) DISPLAY PANEL, PREPARATION METHOD THEREFOR, AND DISPLAY APPARATUS

(71) Applicant: BOE Technology Group Co., Ltd., Beijing (CN)

(72) Inventors: Dongni LIU, Beijing (CN); Minghua XUAN, Beijing (CN); Zhenyu ZHANG, Beijing (CN); Shunhang ZHANG, Beijing (CN); Zhen ZHANG, Beijing (CN); Peirou LI, Beijing (CN); Yunsik IM, Beijing (CN)

(73) Assignee: BOE Technology Group Co., Ltd., Beijing (CN)

(21) Appl. No.: 18/868,791

(22) PCT Filed: Dec. 27, 2023
(86) PCT No.: PCT/CN2023/142277

§ 371 Date: Nov. 25, 2024

(30) Foreign Application Priority Data
Jan. 13, 2023 (CN) 202310072670.3

(51) Int. Cl. H10H 29/49; H10H 29/01; H10H 29/32

(52) U.S. Cl. CPC H10H 29/49; H10H 29/012; H10H 29/32

(57) ABSTRACT

A display panel includes a pixel circuit. The pixel circuit includes a data writing transistor. A first electrode of the data writing transistor is connected to a data signal end. The display panel further includes: a substrate; an active layer located at a side of the substrate; a second conductive layer located at a side of the active layer away from the substrate, where the second conductive layer includes a data signal line, a first adapter part and a second adapter part connected to the first adapter part through a third adapter part; and a third conductive layer located at a side of the second conductive layer away from the substrate, where the third conductive layer includes a conductive part located at an edge of a display region of the display panel, and a fourth adapter part connected to a side of the conductive part facing the data signal line.

### CROSS-REFERENCE TO RELATED APPLICATIONS

The present disclosure claims the priority to the Chinese Patent Application No. 202310072670.3, entitled “DISPLAY PANEL, PREPARATION METHOD THEREFOR, AND DISPLAY APPARATUS”, filed on Jan. 13, 2023, and the entire contents of which are incorporated herein by reference.

### TECHNICAL FIELD

The present disclosure relates to the field of display technologies, and specifically to a display panel and a preparation method therefor, and a display apparatus.

### BACKGROUND

A Micro/Mini-LED is a miniaturized light-emitting diode (LED) array structure with self-luminous display characteristics. Compared with the organic light-emitting diode (OLED) technology that is also self-luminous display, the Micro LED not only has a higher efficiency and a longer life, and is made of a relatively stable material that is not easily affected by the environment, but also can avoid the phenomenon of residual shadow.

In some applications, it is required to use small screens for seamless splicing to achieve the super-large screen display. In the related art, there is a problem of a poor electro-static discharge (ESD).

It should be noted that the information disclosed in the above background section is only used for enhancement of understanding for the background of the present disclosure, and thus may include information that does not constitute the prior art known to those ordinary skilled in the art.

### SUMMARY

An object of the present disclosure is to overcome the deficiencies of the prior art described above, and to provide a display panel and a preparation method therefor, and a display apparatus.

According to an aspect of the present disclosure, there is provided a display panel that includes a pixel circuit, where the pixel circuit includes a data writing transistor, a first electrode of the data writing transistor is connected to a data signal end. The display panel further includes: a substrate; an active layer, located at a side of the substrate, where the active layer includes a first active structure, the first active structure includes a first active part and a second active part connected to the first active part, where the first active part is configured to form a channel region of the data writing transistor, and the second active part is configured to form the first electrode of the data writing transistor; a second conductive layer, located at a side of the active layer away from the substrate, where the second conductive layer includes: a data signal line, connected to the second active part through a via; a first adapter part, connected to an end of the data signal line, where an extension direction of the first adapter part is the same as an extension direction of the data signal line; and a second adapter part, connected to the first adapter part through a third adapter part, where the third adapter part is located in a same conductive layer as the first adapter part and the second adapter part, or located in a different conductive layer from the first adapter part and the second adapter part; and a third conductive layer, located at a side of the second conductive layer away from the substrate, where the third conductive layer includes: a conductive part, located at an edge of a display region of the display panel, where the conductive part is opposite to the data signal line in the extension direction of the data signal line, and the conductive part is configured to form a binding adapter part of the display panel; and a fourth adapter part, connected to a side of the conductive part facing the data signal line. A first end of the second adapter part is connected to the third adapter part, a second end of the second adapter part is connected to the fourth adapter part through a via, and an orthographic projection of the fourth adapter part on the substrate covers an orthographic projection, on the substrate, of the second end of the second adapter part.

In an exemplary embodiment of the present disclosure, an area of the orthographic projection of the fourth adapter part on the substrate is less than an area of an orthographic projection of the conductive part on the substrate.

In an exemplary embodiment of the present disclosure, a ratio of the area of the orthographic projection of the fourth adapter part on the substrate to the area of the orthographic projection of the conductive part on the substrate is less than or equal to ½.

In an exemplary embodiment of the present disclosure, a material of the second conductive layer has a second resistivity, a material of the third conductive layer has a third resistivity, and the second resistivity is greater than the third resistivity.

In an exemplary embodiment of the present disclosure, the fourth adapter part is connected to the second adapter part through a first via, and a number of the first via is multiple.

In an exemplary embodiment of the present disclosure, the third adapter part is located in the second conductive layer.

In an exemplary embodiment of the present disclosure, the display panel further includes a first conductive layer located between the active layer and the second conductive layer; where the third adapter part is located in the first conductive layer, and the third adapter part is connected to the first adapter part and the second adapter part through vias respectively; and a material of the first conductive layer has a first resistivity, a material of the second conductive layer has a second resistivity, and the first resistivity is greater than the second resistivity.

In an exemplary embodiment of the present disclosure, the third adapter part is connected to the second adapter part through a second via, and the third adapter part is connected to the first adapter part through a third via; and a number of the second via is multiple, and/or a number of the third via is multiple.

In an exemplary embodiment of the present disclosure, the multiple second vias are distributed in an array along a row direction and a column direction.

In an exemplary embodiment of the present disclosure, an orthographic projection of the first active structure on the substrate extends along a row direction, and an orthographic projection of the data signal line on the substrate extends along a column direction.

In an exemplary embodiment of the present disclosure, the active layer further includes a second active structure, where an orthographic projection of the second active structure on the substrate extends along the row direction, the second active structure is located at a side of the first active structure along the column direction, the second active structure includes a fourth active part and a fifth active part connected to a side of the fourth active part, the fourth active part is configured to form another channel region of the data writing transistor, the fifth active part is configured to form the first electrode of the data writing transistor, and the fifth active part is connected to the data signal line through a via.

In an exemplary embodiment of the present disclosure, a number of the second active structure is one or multiple; and when the number of the second active structure is multiple, the multiple second active parts are distributed at intervals in the column direction.

In an exemplary embodiment of the present disclosure, the second active structure is separate from the first active structure.

In an exemplary embodiment of the present disclosure, the second active structure is connected to a side of the first active structure in the column direction.

In an exemplary embodiment of the present disclosure, the display panel further includes a first conductive layer, where the first conductive layer is located between the active layer and the second conductive layer; the first conductive layer further includes: a gate signal line, where the gate signal line includes a main body part and a protruding part, an orthographic projection of the main body part on the substrate extends along the row direction, the protruding part is connected to a side of the main body part in the column direction, an orthographic projection of the protruding part on the substrate covers orthographic projections of the first active part and the fourth active part on the substrate, and the protruding part is configured to form a gate of the data writing transistor; and the orthographic projection of the second active structure on the substrate is located between the orthographic projection of the first active structure on the substrate and the orthographic projection of the main body part on the substrate.

In an exemplary embodiment of the present disclosure, the display panel further includes: an insulating layer, covering the third conductive layer at a side of the third conductive layer away from the substrate, where the insulating layer is provided with a fourth via exposing at least a partial structure of the conductive part; a fanout region, located at a non-display side of the display panel, where the fanout region includes a plurality of wirings; a chip, located at the non-display side of the display panel, where the chip is in a binding connection with the wiring of the fanout region; and a side wiring, provided on a side wall of the display panel, and extending along a thickness direction of the substrate, where one end of the side wiring extends to a display side and is connected to the conductive part through the fourth via, and another end of the side wiring extends to the non-display side and is connected to the wiring located in the fanout region; where the wiring located in the fanout region and the side wiring are formed after formation of the fourth via.

According to a second aspect of the present disclosure, there is provided a preparation method for a display panel, used for preparing the display panel described in any embodiment of the present disclosure. The method includes: forming, by using a patterning process, the first active structure in the active layer, where the first active structure includes the first active part and the second active part connected to the first active part, the first active part is configured to form the channel region of the data writing transistor, and the second active part is configured to form the first electrode of the data writing transistor; forming, by using a patterning process, the data signal line, the first adapter part and the second adapter part in the second conductive layer, where the data signal line is connected to the second active part through a via, the first adapter part is connected to the end of the data signal line, the extension direction of the first adapter part is the same as the extension direction of the data signal line, the second adapter part is connected to the first adapter part through the third adapter part, and the third adapter part is located in the same conductive layer as the first adapter part and the second adapter part, or located in the different conductive layer from the first adapter part and the second adapter part; forming, by using a patterning process, the conductive part and the fourth adapter part in the third conductive layer, where the conductive part is located at the edge of the display region of the display panel, the conductive part is opposite to the data signal line in the extension direction of the data signal line, the conductive part is configured to form the binding adapter part of the display panel, the fourth adapter part is connected to the side of the conductive part facing the data signal line, the first end of the second adapter part is connected to the third adapter part, the second end of the second adapter part is connected to the fourth adapter part through a via, and the orthographic projection of the fourth adapter part on the substrate covers the orthographic projection, on the substrate, of the second end of the second adapter part; forming, by using a patterning process, a fourth via on an insulating layer located at a side of the third conductive layer away from the substrate, where the fourth via exposes at least a partial structure of the conductive part; and forming, by using a side process, a wiring in a fanout region and a side wiring, where the side wiring is provided on a side wall of the display panel and extends along a thickness direction of the substrate, one end of the side wiring extends to a display side and is connected to the conductive part through the fourth via, and another end of the side wiring extends to a non-display side and is connected to the wiring located in the fanout region.

According to a third aspect of the present disclosure, there is provided a display apparatus, including the display panel described in any embodiment of the present disclosure.

The display panel provided by the present disclosure is added with the fourth adapter part that is connected to the conductive block forming the binding adapter part, and the fourth adapter part is connected to the data signal line through other adapter parts. As a result, the wiring resistance between the binding adapter part and the data signal line can be increased, which reduces the electro-static current accumulated on the binding adapter part, and thus solves the problem that the static electricity on the binding adapter part is prone to break down the data writing transistor.

It should be understood that the above general description and the subsequent detailed description are merely exemplary and explanatory, and do not limit the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principles of the present disclosure. It is apparent that the accompanying drawings in the following description are only some of the embodiments of the present disclosure, and other accompanying drawings may be obtained based on these drawings without creative labor for those ordinary skilled in the art.

FIG. 1 is a schematic structure diagram of a spliced panel in the related art;

FIG. 2 is a schematic diagram in which a data signal line is connected to a binding adapter part in a display panel according to an embodiment of the present disclosure;

FIG. 3 is a cross-sectional view along a BB direction in FIG. 2;

FIG. 4 is a cross-sectional view along an AA direction in FIG. 2;

FIG. 5 is a schematic circuit diagram of a pixel driving circuit according to an embodiment of the present disclosure;

FIG. 6 is a schematic circuit diagram of a pixel driving circuit according to another embodiment of the present disclosure;

FIG. 7 is a schematic diagram of a connection between a second conductive layer and a third conductive layer in an adapter manner according to another embodiment of the present disclosure;

FIG. 8 is a schematic diagram of a connection between a data signal line and a binding adapter part in a display panel according to another embodiment of the present disclosure;

FIG. 9 is a cross-sectional view along a CC direction in FIG. 8;

FIG. 10 is a schematic structure diagram of a data writing transistor according to an embodiment of the present disclosure;

FIG. 11 is a partially enlarged view at M in FIG. 10;

FIG. 12 is a schematic structure diagram of a data writing transistor according to another embodiment of the present disclosure;

FIG. 13 is a flowchart of a side process in a preparation method of the present disclosure.

### DETAILED DESCRIPTION

Exemplary embodiments are now described more comprehensively with reference to the accompanying drawings. However, the exemplary embodiments are capable of being implemented in a variety of forms, and should not be construed as being limited to the embodiments set forth herein. Rather, the provision of these embodiments allows for the present disclosure to be comprehensive and complete, and conveys the idea of the exemplary embodiments in a comprehensive manner to those skilled in the art. The same reference numerals in the drawings indicate the same or similar structures, and therefore their detailed descriptions will be omitted. In addition, the accompanying drawings are only schematic illustrations of the present disclosure, and are not necessarily drawn to scale.

Although relative terms such as “up” and “down” are used in this specification to describe a relative relationship between one component and another component indicated in the drawings, these terms are used in this specification only for convenience, e. g., in accordance with the direction of the example described in the accompanying drawing. It can be understood that if the device indicated in the drawing is flipped upside down, the component described as being “up” will become the component described as being “down”. When a certain structure is “on” another structure, it may mean that the certain structure is integrally formed on the another structure, or that the certain structure is “directly” arranged on the another structure, or that the certain structure is “indirectly” arranged on the another structure through yet another structure.

The terms “a”, “an”, “the”, “said”, and “at least one” are used for indicating an existence of one or more elements/components/etc. ; and the terms “include” and “have” are used for indicating an open-ended inclusion and mean that there may be additional elements/components/etc. in addition to the listed elements/components/etc. The terms “first”, “second” and “third”, etc. are used merely as markers but not as quantitative limitations to the objects thereof.

A Micro/Mini-LED is a miniaturized LED array structure with self-luminous display characteristics, and each pixel can be addressed to be individually driven to emit light, which has advantages of high brightness, low power consumption, small size, and super-high resolution and color saturation, etc. Compared with the OLED technology that is also self-luminous display, the Micro LED not only has a higher efficiency and a longer life, and is made of a relatively stable material that is not easily affected by the environment, but also can avoid the phenomenon of residual shadow.

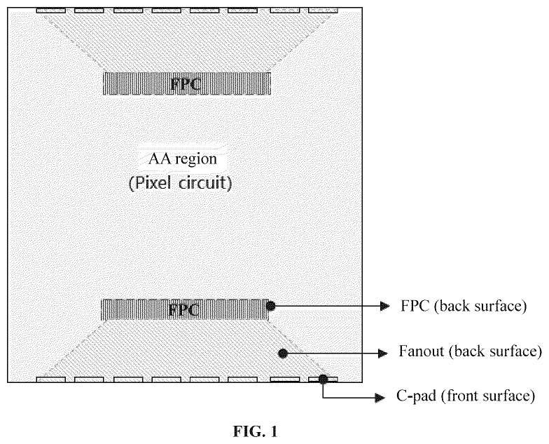

Currently, the application of the LED is mainly for long-distance viewing. It is required to use small screens for splicing to achieve super-large screen display based on a glass substrate, and a seamless splicing scheme is needed. In the seamless splicing scheme, the IC-FPC needs to be bonded to the back surface of the glass substrate, and the signal wiring on the front surface needs to be connected to the back surface. This requires complex side and back processes. The front surface is designed with circuits such as the pixel circuit, the LED chip pad, and the GOA. As shown in FIG. 1, relevant driving signals, such as the power line, the GOA input, the data, and other signals, are led out to the C-pad at the edge of the AA region. Through the later stage process, wirings such as the FPC and Fanout are prepared on the back surface of the backplane. The fanout wiring is connected to the C-pad through the later stage side process. After FPC bonding, the signal is input to relevant circuits such as the pixel circuit and the GOA through FPC-Fan-out->C-pad->AA.

In the later stage side process, there are processes such as film pasting, film tearing, sputter, and etching, which may bring a large amount of static electricity. The C-pad metal is exposed in the air, accumulating a large amount of charge. The static electricity is introduced into the backplane through the C-pad. The amount of the static electricity is large, reaching thousands of volts. A poor ESD occurs at the high resistance position of the TFT Poly connected to the data line in the pixel circuit, causing abnormal pixel display, and greatly reducing the yield of the later stage process. The display panel of the present disclosure focuses on solving the above problems, and the scheme of the present disclosure is described as follows.

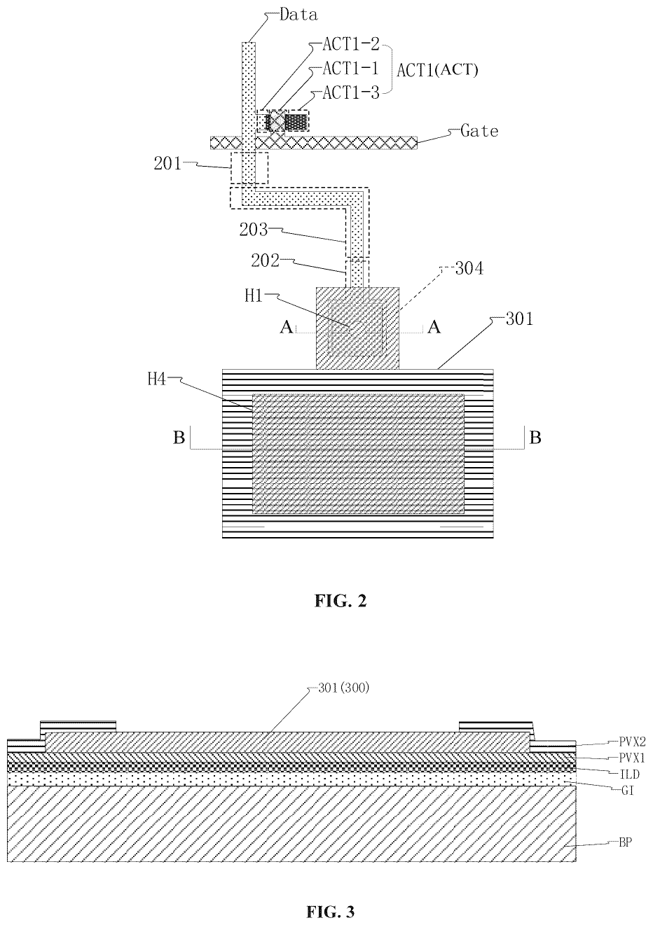

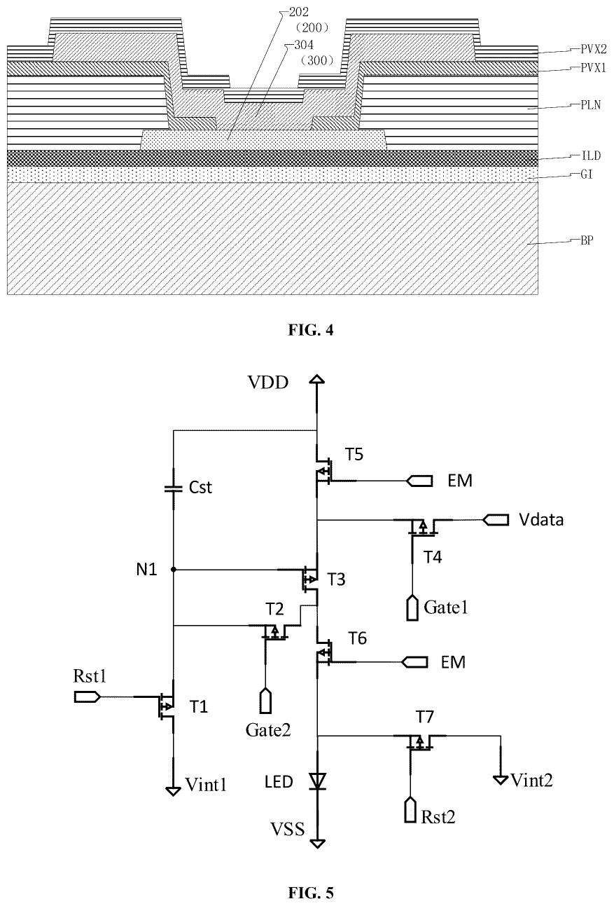

FIG. 2 is a schematic diagram in which a data signal line is connected to a binding adapter part in a display panel according to an embodiment of the present disclosure, FIG. 3 is a cross-sectional view along a BB direction in FIG. 2, and FIG. 4 is a cross-sectional view along an AA direction in FIG. 2. As shown in FIGS. 2 to 4, the display panel of the present disclosure may include a substrate BP, an active layer ACT, a second conductive layer 200, and a third conductive layer 300. The active layer ACT is located at a side of the substrate BP. The active layer ACT may include a first active structure ACT1. The first active structure ACT1 may include a first active part ACT1-1 and a second active part ACT1-2 connected to the first active part ACT1-1. The first active part ACT1-1 may be configured to form a channel region of the data writing transistor. The second active part ACT1-2 may be configured to form a first electrode of the data writing transistor. The second conductive layer 200 is located at a side of the active layer ACT away from the substrate BP. The second conductive layer 200 may include a data signal line Data, a first adapter part 201 and a second adapter part 202. The data signal line Data may be connected to the second active part ACT1-2 through a via. The first adapter part 201 is connected to an end of the data signal line Data. An extension direction of the first adapter part 201 is the same as an extension direction of the data signal line Data. The second adapter part 202 is connected to the first adapter part 201 through a third adapter part 203. The third adapter part 203 is located in a same conductive layer as the first adapter part 201 and the second adapter part 202, or located in a different conductive layer from the first adapter part 201 and the second adapter part 202. The third conductive layer 300 is located at a side of the second conductive layer 200 away from the substrate BP. The third conductive layer 300 may include a conductive part 301 and a fourth adapter part 304. The conductive part 301 is located at an edge of a display region AA of the display panel. The conductive part 301 is opposite to the data signal line Data in the extension direction of the data signal line Data. The conductive part 301 is configured to form a binding adapter part C-Pad of the display panel. The fourth adapter part 304 is connected to a side of the conductive part 301 facing the data signal line Data. A first end of the second adapter part 202 is connected to the third adapter part 203. A second end of the second adapter part 202 is connected to the fourth adapter part 304 through a via. An orthographic projection of the fourth adapter part 304 on the substrate BP covers an orthographic projection, on the substrate BP, of the second end of the second adapter part 202.

The display panel provided by the present disclosure is added with the fourth adapter part 304 that is connected to the conductive block forming the binding adapter part, and the fourth adapter part 304 is connected to the data signal line Data through other adapter parts. As a result, the wiring resistance between the binding adapter part C-Pad and the data signal line Data can be increased, which reduces the electro-static current accumulated on the binding adapter part C-Pad, and thus solves the problem that the static electricity on the binding adapter part C-Pad is prone to break down the data writing transistor.

The display panel described in the present disclosure is a spliced panel, which may have the structural features shown in FIG. 1, that is, a borderless spliced panel is formed through seamless splicing, and a binding adapter part is formed at the edge of the display region and is connected to the wiring of the fanout region located at the non-display side of the panel. For example, as shown in FIGS. 2 and 3, a fourth via H4 is provided on an insulating layer located at a side of the third conductive layer 300 away from the substrate BP. The binding adapter part located at the edge of the display region may be connected to the side wiring through the fourth via H4, the side wiring is connected to the wiring of the fanout region at the non-display side, and in this way, the binding adapter part at the display side is connected to the wiring of the fanout region at the non-display side. As described above, in the spliced panel, the side wiring is formed through the side process in the later stage. During the process of forming the side wiring, the binding adapter part C-Pad may be exposed by the fourth via H4, and a large amount of static electricity generated in the side process may be accumulated on the exposed binding adapter part C-Pad. The static electricity will be introduced into the data signal line Data through the binding adapter part C-Pad, and then into the data writing transistor connected to the data signal line Data through the data signal line Data.

The first active structure ACT1 refers to a semiconductor layer structure that includes a semiconductor part and a conductive part that is processed through a conductive process. The semiconductor part is configured to form the channel region of the data writing transistor, and the conductive part is configured to form the first electrode and the second electrode of the data writing transistor. Specifically, as shown in FIG. 2, the first active structure ACT1 includes a first active part ACT1-1, a second active part ACT1-2 and a third active part ACT1-3. The first active part ACT1-1 is configured to form the channel region of the data writing transistor. The second active part ACT1-2 and the third active part ACT1-3 are connected to two sides of the first active part ACT1-1. The second active part ACT1-2 is configured to form the first electrode of the data writing transistor. The third active part ACT1-3 is configured to form the second electrode of the data writing transistor. In this way, the second active part ACT1-2 is connected to the data signal line Data of the second conductive layer 200 through a via (the data signal line Data is configured to provide the data signal end Vdata in the pixel driving circuit), thereby connecting the first electrode of the fourth transistor to the data signal end Vdata.

The data writing transistor refers to a transistor connected to the data signal line Data and configured to write the data signal on the data signal line Data into the pixel driving circuit. It should be understood that the pixel driving circuit may have different circuit structures, and the present disclosure does not limit the specific circuit structure of the pixel driving circuit.

For example, FIG. 5 is a schematic circuit diagram of a pixel driving circuit according to an embodiment of the present disclosure. As shown in FIG. 5, the pixel driving circuit may include first to seventh transistors T1 to T7 and a storage capacitor Cst. The first electrode of the first transistor T1 is connected to the first node N1, the second electrode of the first transistor T1 is connected to the first initial signal end Vinit1, and the gate of the first transistor T1 is connected to the first reset signal end Rst1. The first electrode of the second transistor T2 is connected to the first node N1, the second electrode of the second transistor T2 is connected to the second electrode of the driving transistor T3, and the gate of the second transistor T2 is connected to the second gate signal end Gate2. The gate of the driving transistor T3 is connected to the first node N1. The first electrode of the fourth transistor T4 is connected to the data signal end Vdata, the second electrode of the fourth transistor T4 is connected to the first electrode of the driving transistor T3, and the gate of the fourth transistor T4 is connected to the first gate signal end Gate1. The first electrode of the fifth transistor T5 is connected to the first power supply end VDD, the second electrode of the fifth transistor T5 is connected to the first electrode of the driving transistor T3, and the gate of the fifth transistor T5 is connected to the enable signal end EM. The first electrode of the sixth transistor T6 is connected to the second electrode of the driving transistor T3, the second electrode of the sixth transistor T6 is connected to the anode of the light-emitting device LED, and the gate of the sixth transistor T6 is connected to the enable signal end EM. The first electrode of the seventh transistor T7 is connected to the second initial signal end Vinit2, the second electrode of the seventh transistor T7 is connected to the anode of the light-emitting device LED, and the gate of the seventh transistor T7 is connected to the second reset signal end Rst2. The cathode of the light-emitting device LED is connected to the second power supply end VSS. One end of the storage capacitor Cst is connected to the first node N1, and another end of the storage capacitor Cst is connected to the first electrode of the fifth transistor T5. In the pixel driving circuit shown in FIG. 5, the fourth transistor T4 is the data writing transistor described in the present disclosure. Specifically, during the charging phase, both the first gate signal end Gatel and the second gate signal end Gate2 output an on level to control the second transistor T2 and the fourth transistor T4 to be turned on, the data signal end Vdata outputs a data signal Vdata, and Vdata+Vth (i.e., the sum of the voltage Vdata and the voltage Vth, where Vth is the threshold voltage of the driving transistor T3) is written into the first node NI and stored in the storage capacitor Cst.

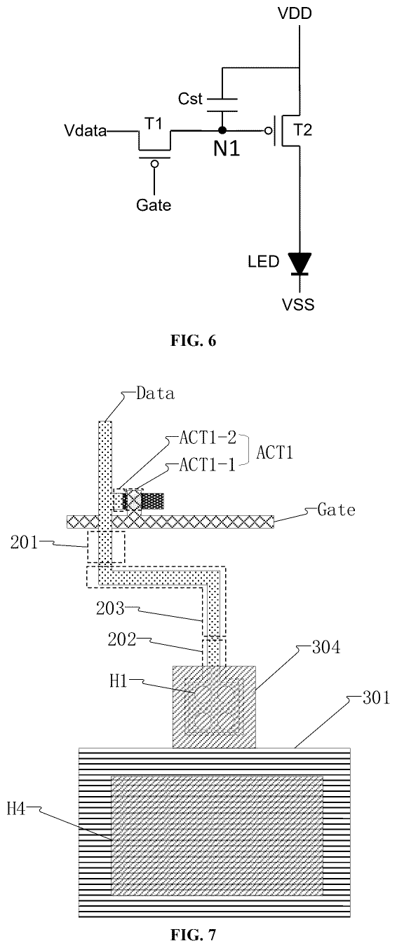

FIG. 6 is a schematic circuit diagram of a pixel driving circuit according to another embodiment of the present disclosure. As shown in FIG. 6, the pixel driving circuit may include a first transistor T1, a second transistor T2 and a storage capacitor Cst. The first electrode of the first transistor T1 is connected to the data signal end Vdata, the second electrode of the first transistor T1 is connected to the first node N1, and the gate of the first transistor T1 is connected to the gate signal end. The first electrode of the second transistor T2 is connected to the first power supply end VDD, the second electrode of the second transistor T2 is connected to the anode of the light-emitting device LED, and the gate of the second transistor T2 is connected to the first node N1. The cathode of the light-emitting device LED is connected to the second power supply end VSS. One end of the storage capacitor Cst is connected to the first node N1, and another end of the storage capacitor Cst is connected to the data signal end Vdata. In the pixel driving circuit shown in FIG. 6, the first transistor T1 is the data writing transistor described in the present disclosure. Specifically, during the charging phase, the gate signal line end Gate outputs an on level to turn on the first transistor T1, and the first transistor T1 writes the data signal of the data signal end Vdata into the first node N1, and the data signal of the data signal end Vdata is stored by the storage capacitor Cst.

It should be understood that FIGS. 5 and 6 are only exemplary illustrations of data writing transistors in different pixel driving circuits, and should not be understood as limitations on the pixel driving circuit of the present disclosure. The transistors connected to the data signal line Data and configured for data signal writing in different pixel driving circuits correspond to the data writing transistors described in the present disclosure, and will not be listed one by one here.

The conductive part 301 is configured to form the binding adapter part C-Pad of the display panel. The binding adapter part C-Pad described in the present disclosure may be understood as a signal adapter part connected to the relevant circuit at the display side and connected to the wiring of the fanout region at the non-display side. As described above, the display panel of the present disclosure is a spliced panel without borders. The binding adapter part C-Pad is located at the edge of the display region AA and connected to the wiring of the fanout region through the side wiring, and transmits the signal on the wiring of the fanout region to relevant circuits in the display region AA such as the pixel driving circuit and the GOA circuit. The side wiring described in the present disclosure refers to the wiring provided on the side wall of the display panel and extending along the thickness direction of the substrate BP. One end of the side wiring extends to the display side and is connected to the binding adapter part C-Pad, and another end of the side wiring extends to the non-display side and is connected to the wiring of the fanout region.

The first adapter part 201 is connected to an end of the data signal line Data, and the extension direction of the first adapter part 201 is the same as the extension direction of the data signal line Data. In other words, the first adapter part 201 is connected to an end of the data signal line Data in the extension direction of the data signal line Data, that is, the first adapter part 201 extends towards the binding adapter part C-Pad located at the edge of the display region AA.

The extension of a certain structure A along a B direction described in the present disclosure refers to the fact that A may include a main part and a secondary part connected to the main part, the main part is a line, line segment, or strip-shaped body, the main part extends along the B direction, and the length of the main part extending along the B direction is greater than the length of the secondary part extending along other directions.

The second adapter part 202 is connected to the first adapter part 201 through the third adapter part 203, that is, a third adapter part 203 is provided between the first adapter part 201 and the second adapter part 202, and the third adapter part 203 is connected to the first adapter part 201 and the second adapter part 202 respectively. In the display panel of the present disclosure, the third adapter part 203 may be located in the same conductive layer as the first adapter part 201 and the second adapter part 202, or may be located in a different conductive layer from the first adapter part 201 and the second adapter part 202. That is, the third adapter part 203 may be located in the second conductive layer 200 or another conductive layer. When the third adapter part 203 is located in the second conductive layer 200, as shown in FIG. 2, the first adapter part 201, the third adapter part 203 and the second adapter part 202 are the wiring structures sequentially connected at an end of the data signal line Data. When the third adapter part 203 is located in another conductive layer, it is equivalent to connecting, in a layer-changing adapter manner, the first adapter part 201 and the second adapter part 202 through the wiring of another conductive layer. For the structure in which the third adapter part 203 is located in another conductive layer, please refer to the introduction of subsequent embodiments.

The fourth adapter part 304 is connected to a side of the conductive part 301 facing the data signal line Data, that is, a fourth adapter part 304 is provided at the side of the binding adapter part C-Pad facing the data signal line Data. The orthographic projection of the fourth adapter part 304 on the substrate BP covers the orthographic projection, on the substrate BP, of the second end of the second adapter part 202. As a result, in the extension process of the second adapter part 202 from its first end to its second end, the second adapter part 202 is terminated when it extends to the position corresponding to the fourth adapter part 304, that is, the second adapter part 202 does not extend further towards the conductive part 301. Therefore, the second adapter part 202 is not directly connected to the conductive part 301, but is connected to the conductive part 301 in an adapter manner through the fourth adapter part 304. In this way, compared with directly connecting the data signal line Data at the binding adapter part C-Pad in a layer-changing adapter manner in the related art, the display panel of the present disclosure at least can increase the wiring resistance between the conductive part 301 and the data signal line Data through the added fourth adapter part 304. As a result, the electro-static current generated by the static electricity accumulated on the fourth adapter part 304 is greatly reduced and does not cause the phenomenon of a large current being introduced into the data signal line Data, which can effectively protect the data writing transistor connected to the data signal line Data from being broken down by the large current.

The orthographic projection of a certain structure A on the substrate covering the orthographic projection of another structure B on the substrate described in the present disclosure may be understood as the contour of the projection of B on the plane of the substrate being completely located inside the contour of the projection of A on the same plane.

In the display panel of the present disclosure, the first conductive layer 100 may be a first gate metal layer Gate, the second conductive layer 200 may be a first source drain metal layer SD1, and the third conductive layer 300 may be a second source drain metal layer SD2. The active layer ACT, the first conductive layer 100, the second conductive layer 200 and the third conductive layer 300 are sequentially stacked at a side of the substrate BP, and insulating layers may be provided between respective conductive layers.

For example, as shown in FIGS. 3 and 4, a gate insulating layer GI may be provided between the active layer ACT and the first conductive layer 100 to insulate the first conductive layer 100 from the active layer ACT. An interlayer insulating layer ILD may be provided between the first conductive layer 100 and the second conductive layer 200. The interlayer insulating layer ILD may insulate the gate of the first conductive layer 100 from the source and drain of the second conductive layer. A planarization layer PLN and a first passivation layer PVX1 may be provided between the second conductive layer 200 and the third conductive layer 300, and a second passivation layer PVX2 may be provided on the third conductive layer 300. The above-described insulating layers may be organic insulating layers or inorganic insulating layers. By providing vias exposing conductive structures on the insulating layer between the two conductive layers, the conductive structures in two adjacent conductive layers are electrically connected. Taking the second passivation layer PVX2 covering the third conductive layer 300 as an example, as shown in FIGS. 2 and 3, the second passivation layer PVX2 is provided with a fourth via H4 at a position of the second passivation layer PVX2 corresponding to the conductive part 301, thereby exposing a portion of the binding adapter part C-Pad. In this way, the binding adapter part C-Pad may be connected to the side wiring through the fourth via H4.

It should be understood that the display panel of the present disclosure may also have other film layers, for example, a light-shielding layer may be further included, and the light-shielding layer may be located between the active layer and the substrate. The bottom gate of the transistor, and the electrode plate of the storage capacitor, etc. may be formed in the light-shielding layer, which will not be elaborated here.

In the display panel of the present disclosure, the resistivity of the material of the second conductive layer 200 and the resistivity of the material of the third conductive layer 300 may be different. For example, the material of the second conductive layer 200 has a second resistivity, and the material of the third conductive layer 300 has a third resistivity. The second resistivity may be greater than the third resistivity. In this way, the contact resistance between the fourth adapter part 304 and the second adapter part 202 can be increased, which further increases the wiring resistance between the conductive part 301 and the data signal line Data, and thus further reduces the electro-static current and effectively protects the data writing transistor from being broken down by the static electricity. For example, the material of the third conductive layer 300 may be copper (Cu), and the material of the second conductive layer 200 may be titanium aluminum titanium (TiAITi) alloy. Of course, in other embodiments, the third conductive layer 300 and the second conductive layer 200 may be made of other materials, and the second resistivity may also be lower than the third resistivity. As long as the resistivity of the material of the second conductive layer and the resistivity of the material of the third conductive layer are different, the purpose of further increasing the wiring resistance can be achieved.

As shown in FIG. 2, in an exemplary embodiment, the third adapter part 203 is located in the second conductive layer 200, that is, the third adapter part 203 is located in the same conductive layer as the first adapter part 201 and the second adapter part 202. At this point, the binding adapter part C-Pad is connected to the data signal line Data through the fourth adapter part 304 of the third conductive layer 300, and the second adapter part 202, the third adapter part 203 and the first adapter part 201 of the second conductive layer 200. From the above analysis, it can be seen that the wiring resistance is increased by adding the fourth adapter part 304, which can reduce the electro-static current.

As shown in FIGS. 2 and 4, the second adapter part 202 located in the second conductive layer 200 is terminated when it extends to the position of the fourth adapter part 304, and is connected to the fourth adapter part 304 through a via.

As shown in FIG. 2, in this exemplary embodiment, the area of the orthographic projection of the fourth adapter part 304 on the substrate BP is less than the area of the orthographic projection of the conductive part 301 on the substrate BP. Therefore, the static electricity accumulated on the binding adapter part C-Pad is gradually introduced into the second adapter part 202, that is, the large current formed by the static electricity will not be all introduced into the second adapter part 202 at the same time, which is equivalent to reducing the electro-static current on the wiring and protecting the data writing transistor from being broken down by the static electricity. For example, the area of the orthographic projection of the fourth adapter part 304 on the substrate BP is s1, the area of the orthographic projection of the conductive part 301 on the substrate BP is s2, and s1/s2 may be less than or equal to ½, for example, it may be ⅕, ¼, ⅓, ½, etc.

As shown in FIG. 2, in an exemplary embodiment, the fourth adapter part 304 is connected to the second adapter part 202 through a first via H1, and the number of the first via HI may be one, that is, the fourth adapter part 304 and the second adapter part 202 are connected to each other through only one via.

In other embodiments, the fourth adapter part 304 and the second adapter part 202 may be connected to each other through a plurality of vias. FIG. 7 is a schematic diagram of a connection between a second conductive layer and a third conductive layer in an adapter manner according to another embodiment of the present disclosure. As shown in FIG. 7, in this exemplary embodiment, the fourth adapter part 304 is connected to the second adapter part 202 through first vias H1, and the number of the first vias H1 is multiple. By setting a plurality of first vias H1, the electro-static current is gradually decreased as it flows from the third conductive layer 300 to the second conductive layer 200, which can avoid the phenomenon of electro-static breakdown at the connection caused by the sudden change of the electro-static current from the large current to the low current. The plurality of first vias H1 may be distributed in an array along the row direction and the column direction, i.e., forming a via structure with a distribution of a plurality of rows and a plurality of columns. In addition, it should be understood that in the display panel of the present disclosure, the size of the via connecting the fourth adapter part 304 and the second adapter part 202 should be comparable to the size of the via at other positions on the same insulating layer in the display region AA, thereby reducing the process difficulty and ensuring the uniformity of the sizes of the vias on the same insulating layer. For example, if a planarization layer PLN and a first passivation layer PVX1 are provided between the second conductive layer 200 and the third conductive layer 300, the hole diameter of the first via HI on the planarization layer PLN is comparable to the hole diameter of the via at other positions on the planarization layer PLN, and the hole diameter of the first via Hl on the first passivation layer PVX1 is comparable to the hole diameter of the via at other positions on the first passivation layer PVX1.

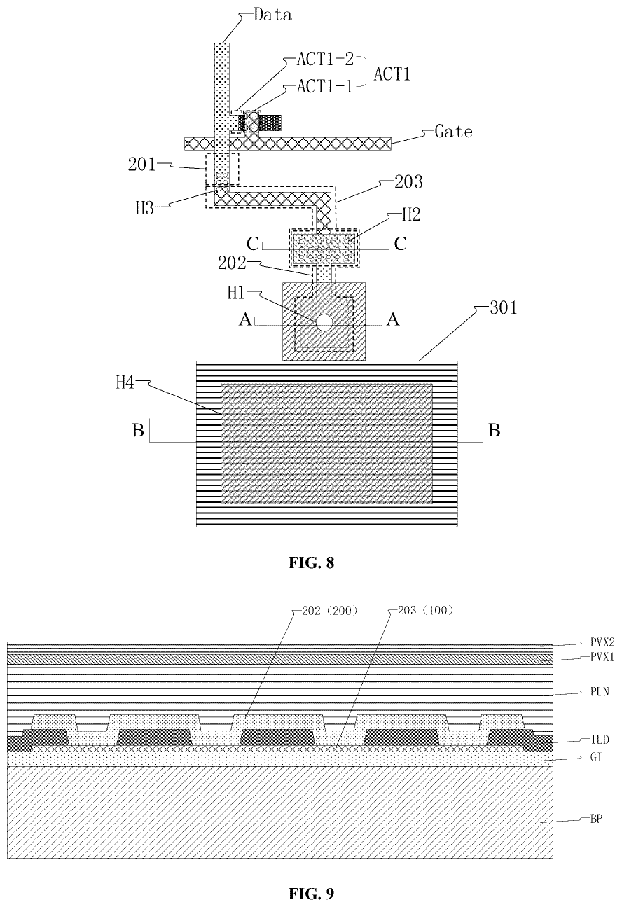

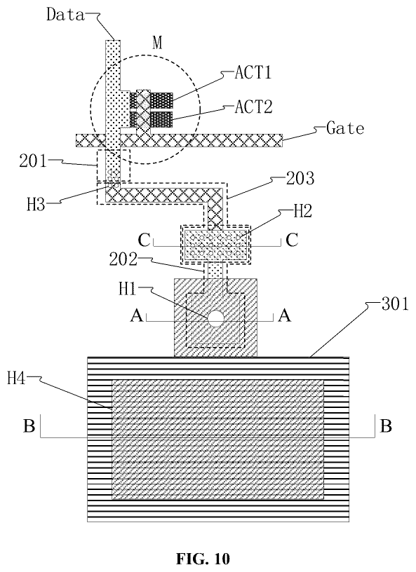

FIG. 8 is a schematic diagram of a connection between a data signal line and a binding adapter part in a display panel according to another embodiment of the present disclosure, and FIG. 9 is a cross-sectional view along a CC direction in FIG. 8. As shown in FIGS. 8 and 9, the third adapter part 203 is located in a different conductive layer from the first adapter part 201 and the second adapter part 202. Specifically, the first adapter part 201 and the second adapter part 202 may be located in the second conductive layer 200, and the third adapter part 203 may be located in the first conductive layer 100. That is, the binding adapter part C-Pad is connected in an adapter manner through the wiring of the second conductive layer 200 and the wiring of the first conductive layer 100. By using the first conductive layer 100 for wiring, the wiring resistance between the data signal line Data and the binding adapter part C-Pad can be further increased, which further reduces the electro-static current. Specifically, the resistivity of the material of the first conductive layer 100 is different from the resistivity of the material of the second conductive layer 200. The material of the first conductive layer 100 has a first resistivity, and the material of the second conductive layer 200 has a second resistivity. The first resistivity may be greater than the second resistivity. Therefore, by placing the third adapter part 203 in the first conductive layer 100, on the one hand, the high resistivity feature of the first conductive layer 100 can be utilized to further increase the resistance of the third adapter part 203. That is, the resistance of the third adapter part 203 in this exemplary embodiment is greater than the resistance of the third adapter part 203 in the scheme shown in FIG. 2. On the other hand, compared with the structure shown in FIG. 2, the contact resistance between the third adapter part 203 and the first adapter part 201, and the contact resistance between the third adapter part 203 and the second adapter part 202 are increased, which is equivalent to further increasing the wiring resistance between the binding adapter part C-Pad and the data signal line Data and further weakening the electro-static current, thereby protecting the data writing transistor from being broken down by the static electricity. For example, the material of the first conductive layer 100 may be molybdenum (Mu), and the material of the second conductive layer 200 may be titanium aluminum titanium (TiAlTi) alloy describe above. Of course, in other embodiments, the first conductive layer 100 and the second conductive layer may be made of other materials. As long as the resistivity of the material of the first conductive layer 100 is greater than the resistivity of the material of the second conductive layer 200, the effect of the structure shown in FIG. 8 can be provided.

As shown in FIG. 8, in an exemplary embodiment, the third adapter part 203 may be connected to the second adapter part 202 through a second via H2. The number of the second via H2 may be multiple. That is, the third adapter part 203 may be connected to the second adapter part 202 through a plurality of vias. The advantage of this arrangement is that because the resistance difference between the first conductive layer 100 and the second conductive layer 200 is large, by setting a plurality of second vias H2, the electro-static current can be gradually reduced, avoiding electro-static breakdown at the connection between the third adapter part 203 and the second adapter part 202 caused by the sudden change of the electro-static current. Of course, in other embodiments, the number of the second via H2 may also be one, and the present disclosure is not limited to this.

As shown in FIG. 8, in an exemplary embodiment, the plurality of second vias H2 may be distributed in an array along the row direction and the column direction, that is, the plurality of second vias H2 form a structure with a plurality of rows and a plurality of columns, such as two rows and four columns, three rows and six columns, etc.

Similarly, as shown in FIG. 8, the first adapter part 201 may be connected to the third adapter part 203 through a third via H3. The number of the third via H3 may be multiple. In this way, by using a plurality of third vias H3, the electro-static current can also be controlled to be gradually reduced, avoiding electro-static breakdown caused by the sudden change of the electro-static current at the connection. Of course, in other embodiments, the number of the third via H3 may also be only one, and the present disclosure is not limited to this.

In addition, it should be understood that the hole diameter of the second via H2 and the hole diameter of the third via H3 here should be comparable to the hole diameters of other vias on the same insulating layer in the display region AA, in order to maintain uniformity of the sizes of the vias on the same insulating layer and reduce the process difficulty. For example, an interlayer insulating layer ILD is provided between the first conductive layer and the second conductive layer 200, that is, the second via H2 and the third via H3 are located on the interlayer insulating layer ILD, then the hole diameter of the second via H2 and the hole diameter of the third via H3 should be comparable to the hole diameters of the vias at other positions on the interlayer insulating layer ILD.

In addition, it should be understood that the cross-sectional view along the AA direction in FIG. 8 may have all the features in FIG. 4, and the cross-sectional view along the BB direction in FIG. 8 may have all the features in FIG. 3, which will not be described in detail here.

As shown in FIGS. 2 and 8, the first conductive layer 100 may include a gate signal line Gate. The gate signal line Gate may include a main body part and a protruding part. The orthographic projection of the main body part on the substrate BP may extend along the row direction. The protruding part is connected to a side of the main body part in the column direction. The orthographic projection of the protruding part on the substrate BP covers the orthographic projection of the first active part ACT1-1 on the substrate BP. The protruding part is configured to form the gate of the data writing transistor.

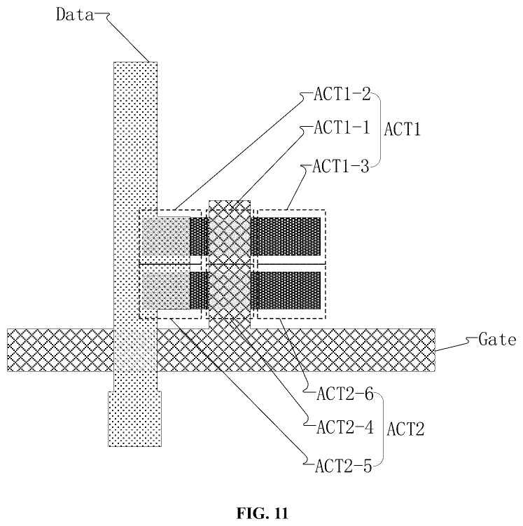

FIG. 10 is a schematic structure diagram of a data writing transistor according to an embodiment of the present disclosure, and FIG. 11 is a partially enlarged view at M in FIG. 10. As shown in FIGS. 10 and 11, in an exemplary embodiment, the active layer ACT may further include a second active structure ACT2. The orthographic projection of the first active structure ACT1 on the substrate BP, and the orthographic projection of the second active structure ACT2 on the substrate BP may both extend along the row direction. The first active structure ACT1 and the second active structure ACT2 are distributed along the column direction. In other words, the second active structure ACT2 is formed at a side of the first active structure ACT1. By adding the second active structure ACT2, the data writing transistor can form a multi-gate structure.

The second active structure ACT2 may include a fourth active part ACT2-4, a fifth active part ACT2-5 and a sixth active part ACT2-6. The fourth active part ACT2-4 may be configured to form another channel region of the data writing transistor. The fifth active part ACT2-5 may be configured to form the first electrode of the data writing transistor. The sixth active part ACT2-6 may be configured to form the second electrode of the data writing transistor. The fifth active part ACT2-5 may be connected to the data signal line Data through a via, thereby connecting the first electrode of the data writing transistor as added to the data signal line Data.

It should be understood that FIG. 10 is illustrated exemplarily only by taking the third adapter part 203 located in the first conductive layer 100 as an example. In the case where the third adapter part 203 is located in the second conductive layer 200, the second active structure ACT2 may also be added to eliminate or reduce the effect of the static electricity on the data writing transistor and to ensure the reliable operation of the data writing transistor.

As shown in FIGS. 10 and 11, in an exemplary embodiment, the second active structure ACT2 may be separate from the first active structure ACT1, that is, a gap is provided between the second active structure ACT2 and the first active structure ACT1, and the two are two independent structures in the active layer ACT. In this way, another data writing transistor can be formed by adding the second active structure ACT2, that is, two data writing transistors in a parallel structure can be formed on the basis of the original first active structure ACT1. In this way, even if the electro-static current breaks down a certain data writing transistor, another data writing transistor connected in parallel can still write the data signal on the data signal line Data into the pixel driving circuit during the charging phase, ensuring the normal operation of the display panel.

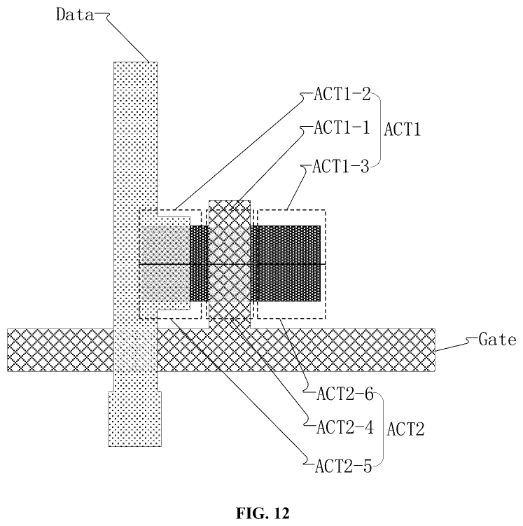

FIG. 12 is a schematic structure diagram of a data writing transistor according to another embodiment of the present disclosure. As shown in FIG. 12, in another exemplary embodiment, the second active structure ACT2 may be connected to the first active structure ACT1, that is, the second active structure ACT2 and the first active structure ACT1 form a larger active structure, which is equivalent to increasing the width of the channel region, the width of the source region, and the width of the drain region of the data writing transistor, thereby increasing the current channel. It is apparent that the increased current channel can reduce the electro-static current, which can further reduce the probability of electro-static breakdown of the electro-static current at the position where the data writing transistor is connected to the data signal line Data, and further improves the reliability of the display panel.

In an exemplary embodiment, the number of the second active part ACT1-2 structure may be one. When the second active structure ACT2 is connected to the first active structure ACT1, it is equivalent to increasing the width of the channel region and the width of the first electrode of the data writing transistor by adding a second active structure ACT2. When the second active structure ACT2 is not connected to the first active structure ACT1, it is equivalent to forming a redundant data writing transistor through the added second active structure ACT2.

In other embodiments, the number of the second active structure ACT2 may be multiple. For example, a plurality of second active structures ACT2 may be separate from each other. In this way, a plurality of data writing transistors in a parallel structure can be formed. When the static electricity forms electro-static breakdown at the connection between the data signal line Data and the second active part ACT1-2 or any fifth active part ACT2-5, other fourth active structures can also be used to form the backup data writing transistor for data signal writing during the charging phase, ensuring the normal operation of the display panel.

The present disclosure also provides a preparation method for a display panel, and the preparation method is used for preparing the display panel described in any of the embodiments described above in the present disclosure. The preparation method may include the following steps S110 to S150.

At S110, the first active structure ACT1 is formed in the active layer ACT by using a patterning process. The first active structure ACT1 includes the first active part ACT1-1 and the second active part ACT1-2 connected to the first active part ACT1-1. The first active part ACT1-1 is configured to form the channel region of the data writing transistor, and the second active part ACT1-2 is configured to form the first electrode of the data writing transistor.

In some embodiments of the present disclosure, the second active structure ACT2 may also be formed in the active layer ACT, and the second active structure ACT2 is also configured to form the channel region, the first electrode and the second electrode of the data writing transistor. The orthographic projection of the first active structure ACT1 on the substrate, and the orthographic projection of the second active structure ACT2 on the substrate may both extend along the row direction. The second active structure ACT2 is located at a side of the first active structure ACT1 in the column direction. The second active structure ACT2 may or may not be connected to the first active structure ACT1. By adding the second active structure ACT2, the current channel can be increased, and the increased current channel can reduce the electro-static current, which can reduce the probability of electro-static breakdown of the electro-static current at the position where the data writing transistor is connected to the data signal line Data, and improves the reliability of the display panel. The relevant features of the second active structure ACT2 may be referred to the introduction of the above embodiments, and will not be described in detail here.

At S120, the data signal line Data, the first adapter part 201 and the second adapter part 202 are formed in the second conductive layer 200 by using a patterning process. The data signal line Data is connected to the second active part ACT1-2 through a via. The first adapter part 201 is connected to an end of the data signal line Data. The extension direction of the first adapter part 201 is the same as the extension direction of the data signal line Data. The second adapter part 202 is connected to the first adapter part 201 through the third adapter part 203. The third adapter part 203 is located in the same conductive layer as the first adapter part 201 and the second adapter part 202, or located in a different conductive layer from the first adapter part 201 and the second adapter part 202.

In some embodiments, the third adapter part 203 may be located in the second conductive layer, or may be located in the first conductive layer. The relevant features of the third adapter part 203 may be referred to the introduction of the above embodiments, and will not be described in detail here.

At S130, the conductive part 301 and the fourth adapter part 304 are formed in the third conductive layer 300 by using a patterning process. The conductive part 301 is located at the edge of the display region of the display panel, and is opposite to the data signal line Data in the extension direction of the data signal line Data. The conductive part 301 is configured to form the binding adapter part C-Pad of the display panel. The fourth adapter part 304 is connected to a side of the conductive part 301 facing the data signal line Data. The first end of the second adapter part 202 is connected to the third adapter part 203, and the second end of the second adapter part 202 is connected to the fourth adapter part 304 through a via. The orthographic projection of the fourth adapter part 304 on the substrate covers the orthographic projection, on the substrate, of the second end of the second adapter part 202.

By forming the fourth adapter part 304, the present disclosure can increase the wiring resistance between the binding adapter part C-Pad and the data signal line, thereby reducing the electro-static current.

At S140, the fourth via H4 is formed on the insulating layer located at a side of the third conductive layer 300 away from the substrate, where the fourth via H4 exposes at least a partial structure of the conductive part 301. The fourth via exposes at least a partial structure of the conductive part 301, which is used for connection with the side wiring formed in subsequent steps.

At 150, the wiring of the fanout region and the side wiring are formed by using a side process, where the side wiring is provided on the side wall of the display panel and extends along the thickness direction of the substrate, one end of the side wiring extends to the display side and is connected to the conductive part 301 through the fourth via H4, and another end of the side wiring extends to the non-display side and is connected to the wiring located in the fanout region.

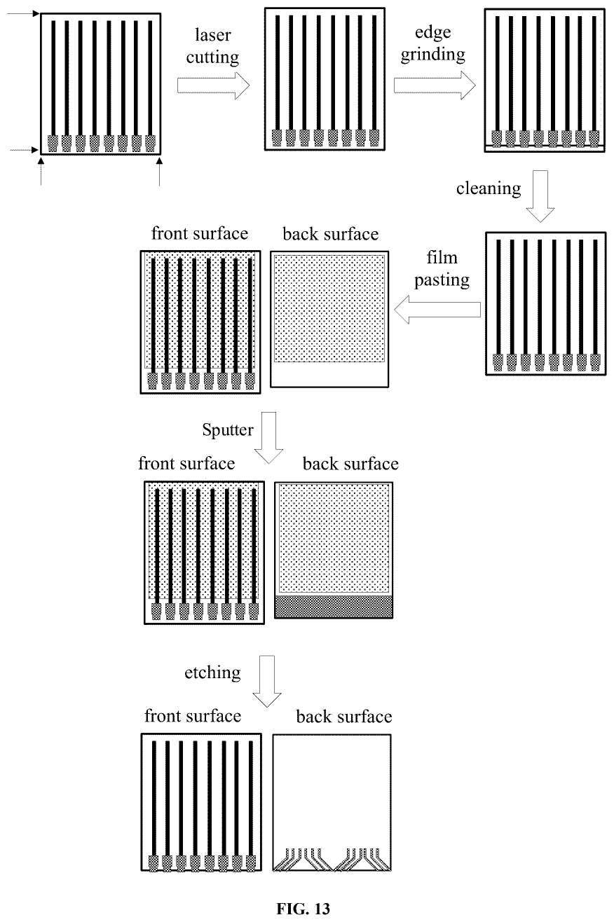

As shown in FIG. 13, for example, side processes may include laser cutting, edge grinding, cleaning, film pasting, sputter, etching, etc. After the above process steps, a metal layer may be formed at the display side of the display panel corresponding to the binding adapter part C-Pad, the side wiring may be formed on the side wall of the panel, and the wiring of the fanout region may be formed at the non-display side of the panel. Therefore, the binding adapter part C-Pad at the display side can be connected to the wiring of the fanout region at the non-display side through the side wiring. The above-described side processes such as film pasting, film tearing, sputter, etching, etc. all bring a large amount of static electricity. The binding adapter part C-Pad is exposed to the air, accumulating a large amount of charge. The static electricity is introduced into the backplane through the binding adapter part C-Pad, and the amount of the static electricity is large, reaching thousands of volts. The present disclosure uses the fourth adapter part 304, the second adapter part 202, the third adapter part 203, and the first adapter part 201 formed in steps S 110 to 140 for connection in an adapter manner, which can increase the wiring resistance between the binding adapter part C-Pad and the data signal line Data, thereby reducing the electro-static current. In this way, the method of the present disclosure can effectively solve the problem of breakdown of the data writing transistor caused by the electro-static current generated in the side process entering the data writing transistor through the data signal line Data, and improve the yield of the subsequent processes.

The present disclosure also provides a display apparatus that may include the display panel described in any of the above embodiments of the present disclosure.

After considering the specification and practicing the invention disclosed herein, those skilled in the art will easily come up with other embodiments of the present disclosure. The purpose of the present application is to cover any variations, uses or adaptations of the present disclosure, and these variations, uses or adaptations follow the general principles of the present disclosure and include common knowledge or customary means in the technical field that is not disclosed in the present disclosure. The specification and embodiments are only considered exemplary, and the true scope and spirit of the present disclosure are indicated by the accompanying claims.

1. A display panel, comprising a pixel circuit, wherein the pixel circuit comprises a data writing transistor, a first electrode of the data writing transistor is connected to a data signal end, and the display panel further comprises:
a substrate;
an active layer, located at a side of the substrate, wherein the active layer comprises:
a first active structure, comprising a first active part and a second active part connected to the first active part, wherein the first active part is configured to form a channel region of the data writing transistor, and the second active part is configured to form the first electrode of the data writing transistor;
a second conductive layer, located at a side of the active layer away from the substrate, wherein the second conductive layer comprises:
a data signal line, connected to the second active part through a fifth via;
a first adapter part, connected to an end of the data signal line, wherein an extension direction of the first adapter part is the same as an extension direction of the data signal line; and
a second adapter part, connected to the first adapter part through a third adapter part; wherein the third adapter part is located in a same conductive layer as the first adapter part and the second adapter part, or located in a different conductive layer from the first adapter part and the second adapter part; and
a third conductive layer, located at a side of the second conductive layer away from the substrate, wherein the third conductive layer comprises:
a conductive part, located at an edge of a display region of the display panel, wherein the conductive part is opposite to the data signal line in the extension direction of the data signal line, and the conductive part is configured to form a binding adapter part of the display panel; and
a fourth adapter part, connected to a side of the conductive part facing the data signal line;
wherein a first end of the second adapter part is connected to the third adapter part, a second end of the second adapter part is connected to the fourth adapter part through at least one first via, and an orthographic projection of the fourth adapter part on the substrate covers an orthographic projection, on the substrate, of the second end of the second adapter part.

2. The display panel according to claim 1, wherein an area of the orthographic projection of the fourth adapter part on the substrate is less than an area of an orthographic projection of the conductive part on the substrate.

3. The display panel according to claim 2, wherein a ratio of the area of the orthographic projection of the fourth adapter part on the substrate to the area of the orthographic projection of the conductive part on the substrate is less than or equal to ½.

4. The display panel according to claim 1, wherein a material of the second conductive layer has a second resistivity, a material of the third conductive layer has a third resistivity, and the second resistivity is greater than the third resistivity.

5. (canceled)

6. The display panel according to claim 1, wherein the third adapter part is located in the second conductive layer.

7. The display panel according to claim 1, further comprising:
a first conductive layer, located between the active layer and the second conductive layer; wherein
the third adapter part is located in the first conductive layer, and
a material of the first conductive layer has a first resistivity, a material of the second conductive layer has a second resistivity, and the first resistivity is greater than the second resistivity.

8. The display panel according to claim 7, wherein the third adapter part is connected to the second adapter part through a plurality of second vias, and the third adapter part is connected to the first adapter part through a plurality of third vias.

9. The display panel according to claim 8, wherein the plurality of second vias are distributed in an array along a row direction and a column direction.

10. The display panel according to claim 1, wherein an orthographic projection of the first active structure on the substrate extends along a row direction, and an orthographic projection of the data signal line on the substrate extends along a column direction.

11. The display panel according to claim 10, wherein the active layer further comprises:
at least one second active structure, wherein an orthographic projection of the second active structure on the substrate extends along the row direction, the second active structure is located at a side of the first active structure along the column direction, the second active structure comprises a fourth active part and a fifth active part connected to a side of the fourth active part, the fourth active part is configured to form another channel region of the data writing transistor, the fifth active part is configured to form the first electrode of the data writing transistor, and the fifth active part is connected to the data signal line through a sixth via.

12. The display panel according to claim 11, wherein
the at least one second active structure comprises a plurality of second active structures, and the plurality of second active structures are distributed at intervals in the column direction.

13. The display panel according to claim 11, wherein the second active structure is separate from the first active structure.

14. The display panel according to claim 11, wherein the second active structure is connected to the side of the first active structure in the column direction.

15. The display panel according to claim 11, further comprising a first conductive layer, wherein the first conductive layer is located between the active layer and the second conductive layer;
the first conductive layer comprises:
a gate signal line, wherein the gate signal line comprises a main body part and a protruding part, an orthographic projection of the main body part on the substrate extends along the row direction, the protruding part is connected to a side of the main body part in the column direction, an orthographic projection of the protruding part on the substrate covers orthographic projections of the first active part and the fourth active part on the substrate, and the protruding part is configured to form a gate of the data writing transistor; and
the orthographic projection of the second active structure on the substrate is located between the orthographic projection of the first active structure on the substrate and the orthographic projection of the main body part on the substrate.

16. The display panel according to claim 1, further comprising:
an insulating layer, covering the third conductive layer at a side of the third conductive layer away from the substrate, wherein the insulating layer is provided with a fourth via exposing at least a partial structure of the conductive part;
a fanout region, located at a non-display side of the display panel, wherein the fanout region comprises a plurality of wirings;
a chip, located at the non-display side of the display panel, wherein the chip is in a binding connection with the wiring of the fanout region; and
a side wiring, provided on a side wall of the display panel, and extending along a thickness direction of the substrate, wherein one end of the side wiring extends to a display side of the display panel and is connected to the conductive part through the fourth via, and another end of the side wiring extends to the non-display side and is connected to the wiring located in the fanout region; wherein
the wiring located in the fanout region and the side wiring are formed after formation of the fourth via.

17. A preparation method for a display panel, used for preparing a display panel according wherein the display panel comprises a pixel circuit, the pixel circuit comprises a data writing transistor, and a first electrode of the data writing transistor is connected to a data signal end.
the display panel further comprises:
a substrate;
an active layer, located at a side of the substrate, wherein the active layer comprises:
a first active structure, comprising a first active part and a second active part connected to the first active part, wherein the first active part is configured to form a channel region of the data writing transistor, and the second active part is configured to form the first electrode of the data writing transistor;
a second conductive layer, located at a side of the active layer away from the substrate, wherein the second conductive layer comprises:
a data signal line, connected to the second active part through a fifth via;
a first adapter part, connected to an end of the data signal line, wherein an extension direction of the first adapter part is the same as an extension direction of the data signal line; and
a second adapter part, connected to the first adapter part through a third adapter part; wherein the third adapter part is located in a same conductive layer as the first adapter part and the second adapter part, or located in a different conductive layer from the first adapter part and the second adapter part; and
a third conductive layer, located at a side of the second conductive layer away from the substrate, wherein the third conductive layer comprises:
a conductive part, located at an edge of a display region of the display panel, wherein the conductive part is opposite to the data signal line in the extension direction of the data signal line, and the conductive part is configured to form a binding adapter part of the display panel; and
a fourth adapter part, connected to a side of the conductive part facing the data signal line;
wherein a first end of the second adapter part is connected to the third adapter part, a second end of the second adapter part is connected to the fourth adapter part through at least one first via, and an orthographic projection of the fourth adapter part on the substrate covers an orthographic projection, on the substrate, of the second end of the second adapter part; and
the method comprises:
forming, by using a first patterning process, the first active structure in the active layer, wherein the first active structure comprises the first active part and the second active part connected to the first active part, the first active part is configured to form the channel region of the data writing transistor, and the second active part is configured to form the first electrode of the data writing transistor;
forming, by using a second patterning process, the data signal line, the first adapter part and the second adapter part in the second conductive layer, wherein the data signal line is connected to the second active part through the fifth via, the first adapter part is connected to the end of the data signal line, the extension direction of the first adapter part is the same as the extension direction of the data signal line, the second adapter part is connected to the first adapter part through the third adapter part, and the third adapter part is located in the same conductive layer as the first adapter part and the second adapter part, or located in the different conductive layer from the first adapter part and the second adapter part;
forming, by using a third patterning process, the conductive part and the fourth adapter part in the third conductive layer, wherein the conductive part is located at the edge of the display region of the display panel, the conductive part is opposite to the data signal line in the extension direction of the data signal line, the conductive part is configured to form the binding adapter part of the display panel, the fourth adapter part is connected to the side of the conductive part facing the data signal line, the first end of the second adapter part is connected to the third adapter part, the second end of the second adapter part is connected to the fourth adapter part through the at least one first via, and the orthographic projection of the fourth adapter part on the substrate covers the orthographic projection, on the substrate, of the second end of the second adapter part;
forming, by using a fourth patterning process, a fourth via on an insulating layer located at a side of the third conductive layer away from the substrate, wherein the fourth via exposes at least a partial structure of the conductive part; and
forming, by using a side process, a wiring in a fanout region and a side wiring, wherein the side wiring is provided on a side wall of the display panel and extends along a thickness direction of the substrate, one end of the side wiring extends to a display side of the display panel and is connected to the conductive part through the fourth via, and another end of the side wiring extends to a non-display side of the display panel and is connected to the wiring located in the fanout region.

18. A display apparatus, comprising a display panel wherein the display panel comprises a pixel circuit, the pixel circuit comprises a data writing transistor, a first electrode of the data writing transistor is connected to a data signal end, and the display panel further comprises:
a substrate;
an active layer, located at a side of the substrate, wherein the active layer comprises:
a first active structure, comprising a first active part and a second active part connected to the first active part, wherein the first active part is configured to form a channel region of the data writing transistor, and the second active part is configured to form the first electrode of the data writing transistor;
a second conductive layer, located at a side of the active layer away from the substrate, wherein the second conductive layer comprises:
a data signal line, connected to the second active part through a fifth via;
a first adapter part, connected to an end of the data signal line, wherein an extension direction of the first adapter part is the same as an extension direction of the data signal line; and
a second adapter part, connected to the first adapter part through a third adapter part; wherein the third adapter part is located in a same conductive layer as the first adapter part and the second adapter part, or located in a different conductive layer from the first adapter part and the second adapter part; and
a third conductive layer, located at a side of the second conductive layer away from the substrate, wherein the third conductive layer comprises:
a conductive part, located at an edge of a display region of the display panel, wherein the conductive part is opposite to the data signal line in the extension direction of the data signal line, and the conductive part is configured to form a binding adapter part of the display panel; and
a fourth adapter part, connected to a side of the conductive part facing the data signal line;
wherein a first end of the second adapter part is connected to the third adapter part, a second end of the second adapter part is connected to the fourth adapter part through at least one first via, and an orthographic projection of the fourth adapter part on the substrate covers an orthographic projection, on the substrate, of the second end of the second adapter part.
